(19) United States
(12) Patent Application Publication
(10) Pub. No.: US 2011/0074012 A1
(43) Pub. Date: Mar. 31, 2011

(54) Substrate with built-in semiconductor element, and method of fabricating substrate with built-in semiconductor element

(75) Inventor: Masanori Itoh, Tokyo (JP)

(73) Assignee: OKI ELECTRIC INDUSTRY CO., LTD., Tokyo (JP)

(21) Appl. No.: 12/923,579

(22) Filed: Sep. 28, 2010

(30) Foreign Application Priority Data
Sep. 29, 2009 (JP) 2009-224672

(51) Int. Cl. H01L 23/66

(52) U.S. Cl. 257/728; 257/E23.002

(57) ABSTRACT

There is provided a substrate with a built-in semiconductor element, including: a first substrate at which a wiring layer is layered on a dielectric layer; a semiconductor element that is structured to include a distributed constant circuit, and at which plural bonding pads are formed at a peripheral region of a surface that faces the first substrate, and that is electrically connected to the wiring layer by an electrically-conductive member that has electrical conductivity and corresponds to the plural bonding pads; a supporting member that is disposed at an inner side region that is further toward an inner side than the peripheral region of the semiconductor element, and that is interposed between the semiconductor element and the first substrate and supports the semiconductor element; and a second substrate that is laminated to the first substrate and the semiconductor element.

### CROSS-REFERENCE TO RELATED APPLICATION

This application is based on and claims priority under 35 USC 119 from Japanese Patent Application No. 2009-224672 filed on Sep. 29, 2009, the disclosure of which is incorporated by reference herein.

### BACKGROUND

1. Technical Field

The present invention relates to a substrate with a built-in semiconductor element, in which a semiconductor element is incorporated within a substrate, and to a method of fabricating a substrate with a built-in semiconductor element.

2. Related Art

In recent years, in order to make semiconductor devices more compact and higher-density, there are cases in which a semiconductor element is incorporated within a substrate.

In such cases, a double-sided copper-clad laminated plate, that is formed by copper plates being laminated onto both surfaces of a dielectric layer, is used as the substrate, and, after a semiconductor element is packaged, an underfill material is filled between the semiconductor element and the double-sided copper-clad laminated plate. Then, an adhesive is applied on the double-sided copper-clad laminated plate and the semiconductor element, and a single-sided copper-clad laminated plate is adhered thereto.

The underfill material fixes the packaged position of the semiconductor element, and protects the semiconductor element from load that arises due to the laminating of the single-sided copper-clad laminated plate and that is applied to the semiconductor element.

Methods of fabricating such a substrate with a built-in semiconductor element are disclosed in Japanese Patent Applications Laid-Open (JP-A) Nos. 2008-10885, 2006-245104, 2005-39094, and 2003-142832.

However, at the substrate with a built-in semiconductor element, the periphery of the semiconductor element is covered by the dielectric layer and the dielectric that is the underfill material. Therefore, there are cases in which the operation of the semiconductor element is affected by the dielectric constant or the dielectric dissipation factor of the dielectric. When the operating frequency of the semiconductor element is high, operation is easily affected by the dielectric.

Specifically, the signal lines of the circuit pattern that is formed on the surface of the semiconductor element are designed such that the characteristic impedance on the semiconductor element becomes a predetermined value (e.g., 50Ω), but the characteristic impedance may change due to the effects of the dielectric that covers the semiconductor element. Further, the higher the dielectric constant of the dielectric that covers the semiconductor element, the greater the parasitic capacity that is generated, and there are cases in which high-frequency operation of the semiconductor element is hindered.

In particular, in a substrate with a built-in semiconductor element that incorporates therein a semiconductor element, such as an MMIC (Monolithic Microwave Integrated Circuit) that is structured to include a distributed constant circuit and that operates in a high-frequency band (millimeter wave band), due to the underfill material that is a dielectric being filled between the semiconductor element and the substrate, the semiconductor element is affected by the underfill material, and deterioration of the high-frequency electrical characteristics, such as shifting of the operating frequency, a decrease in gain, and the like, occurs.

### SUMMARY

The present invention was made in order to overcome the above-described drawbacks, and an object thereof is to provide a substrate with a built-in semiconductor element and a method of fabricating a substrate with a built-in semiconductor element, that suppress effects of a dielectric on a semiconductor element that is structured to include a distributed constant circuit, and that can protect the semiconductor element from load applied thereto at the time of fabrication.

In order to achieve the above-described object, a first aspect of the present invention provides a substrate with a built-in semiconductor element, including:

a first substrate at which a wiring layer is layered on a dielectric layer;

a semiconductor element that is structured to include a distributed constant circuit, and at which plural bonding pads are formed at a peripheral region of a surface that faces the first substrate, and that is electrically connected to the wiring layer by an electrically-conductive member that has electrical conductivity and corresponds to the plural bonding pads;

a supporting member that is disposed at an inner side region that is further toward an inner side than the peripheral region of the semiconductor element, and that is interposed between the semiconductor element and the first substrate and supports the semiconductor element; and

a second substrate that is laminated to the first substrate and the semiconductor element.

In accordance with the substrate with a built-in semiconductor element of the first aspect of the present invention, the plural bonding pads, that are formed at the peripheral region of the semiconductor element that is structured to include a distributed constant circuit, are electrically connected to the wiring layer of the substrate by an electrically-conductive member that has electrical conductivity, and the supporting member is interposed between the first substrate and the inner side region. Therefore, the load that is applied to the semiconductor element at the time of fabrication is dispersed and supported. Therefore, without using an underfill material that is a dielectric, the semiconductor element can be protected from load, and the effects of a dielectric on the semiconductor element that is structured to include a distributed constant circuit can be suppressed.

A second aspect of the present invention provides the substrate with a built-in semiconductor element of the aspect, wherein

signal lines are formed at the inner side region of the semiconductor element, and

the supporting member is disposed at a region other than regions where the signal lines are formed.

Due thereto, because an air layer is formed between the signal lines of the semiconductor element and the dielectric layer that structures the substrate, effects of a dielectric on the operation of the semiconductor element can be more effectively suppressed.

A third aspect of the present invention provides the substrate with a built-in semiconductor element of the second aspect, wherein

at the first substrate, the wiring layer is layered at a region that faces the peripheral region of the semiconductor element and at a region that faces the inner side region,

at the semiconductor element, plural bonding pads are formed at the inner side region, and

the supporting member is plural connecting members that are electrically-conductive and are formed so as to correspond to the plural bonding pads formed at the inner side region, and that electrically connect the wiring layer, that is layered at the region of the first substrate that faces the inner side region, and the plural bonding pads that are formed at the inner side region.

Due thereto, the load that is applied to the semiconductor element and that arises when the second substrate is laminated, is dispersed by the bonding pads, that are formed at the inner side region, and the supporting member, and the semiconductor element is protected from the load. Further, an air layer is generated between the semiconductor element and the dielectric layer. Therefore, effects of a dielectric on the operation of the semiconductor element can be suppressed more effectively.

A fourth aspect of the present invention provides the substrate with a built-in semiconductor element of the third aspect, wherein, at the semiconductor element, the plural bonding pads, that are connected to the wiring layer by the connecting members, are formed randomly at the inner side region.

Due thereto, standing waves can be prevented from being generated at the substrate with a built-in semiconductor element.

A fifth aspect of the present invention provides the substrate with a built-in semiconductor element of the first aspect, wherein the supporting member is a sheet-shaped member that includes a dielectric.

Due thereto, the load that is applied to the semiconductor element and that arises when the second substrate is laminated, is dispersed by the sheet-shaped member, and the semiconductor element is protected from this load. Further, the range of selection of dielectrics for supporting the semiconductor element can be broadened.

A sixth aspect of the present invention provides the substrate with a built-in semiconductor element of the fifth aspect, wherein

the semiconductor element comprises plural circuits having different operating frequencies, or comprises plural semiconductor elements having circuits having different operating frequencies, and

the sheet-shaped member is structured so as to include plural dielectrics at which at least one of a dielectric constant and a dielectric dissipation factor differ in accordance with the operating frequencies of the circuits of the semiconductor element.

Due thereto, even if the semiconductor element is structured by combining plural circuits that have different operating frequencies, dielectrics that are respectively suited to the respective circuits can be disposed between the semiconductor element and the first substrate.

A seventh aspect of the present invention provides the substrate with a built-in semiconductor element of the fifth aspect, wherein

the semiconductor element comprises plural circuits having different operating frequencies, or comprises plural semiconductor elements having circuits having different operating frequencies,

the sheet-shaped member is disposed so as to correspond to a position of the circuit that has a relatively high operating frequency, and

an underfill material is filled so as to correspond to a position of the circuit having a relatively low operating frequency.

Due thereto, effects of a dielectric on the semiconductor element are suppressed, and the fixing of the semiconductor element to the substrate can be made to be secure.

An eighth aspect of the present invention provides a method of fabricating a substrate with a built-in semiconductor element, including:

forming plural bonding pads at a semiconductor element that is structured to include a distributed constant circuit, at a peripheral region of a surface of the semiconductor element which surface faces a first substrate at which a wiring layer is layered on a dielectric layer;

electrically connecting the semiconductor element and the wiring layer of the first substrate by an electrically-conductive member that has electrical conductivity and corresponds to the plural bonding pads, and interposing a supporting member between the first substrate and an inner side region of the semiconductor element that is further toward an inner side than the peripheral region, and packaging the semiconductor element on the first substrate; and

laminating a second substrate on the first substrate and the semiconductor element.

Due thereto, effects of a dielectric on the semiconductor element, that is structured to include a distributed constant circuit, are suppressed, and the semiconductor element can be protected from load that is applied thereto at the time of fabrication.

As described above, in accordance with the present invention, there are the excellent effects that the effects of a dielectric on the semiconductor element, that is structured to include a distributed constant circuit, are suppressed, and the semiconductor element can be protected from load that is applied thereto at the time of fabrication.

### BRIEF DESCRIPTION OF THE DRAWINGS

Exemplary embodiments of the present invention will be described in detail based on the following figures, wherein:

FIG. 1 is a drawing showing a substrate with a built-in semiconductor element relating to a first exemplary embodiment;

FIGS. 2A and 2B are drawings showing, in the processes of fabricating the substrate with a built-in semiconductor element relating to the first exemplary embodiment, a state in which a process of flip-chip packaging a semiconductor element on a substrate is finished;

FIGS. 3A and 3B are drawings showing, in the processes of fabricating the substrate with a built-in semiconductor element relating to the first exemplary embodiment, a state in which, after flip-chip packaging the semiconductor element, a process of applying an adhesive is finished;

FIGS. 4A and 4B are drawings showing, in the processes of fabricating the substrate with a built-in semiconductor element relating to the first exemplary embodiment, a state in which, after applying the adhesive, a process of laminating a substrate is finished;

FIG. 5 is a drawing showing a substrate with a built-in semiconductor element relating to a second exemplary embodiment;

FIGS. 6A and 6B are drawings showing, in the processes of fabricating the substrate with a built-in semiconductor element relating to the second exemplary embodiment, a state in which a process of disposing a sheet-shaped member on a substrate is finished;

FIGS. 7A and 7B are drawings showing, in the processes of fabricating the substrate with a built-in semiconductor element relating to the second exemplary embodiment, a state in which a process of flip-chip packaging a semiconductor element on the substrate is finished;

FIGS. 8A and 8B are drawings showing, in the processes of fabricating the substrate with a built-in semiconductor element relating to the second exemplary embodiment, a state in which, after flip-chip packaging the semiconductor element, a process of applying an adhesive is finished;

FIGS. 9A and 9B are drawings showing, in the processes of fabricating the substrate with a built-in semiconductor element relating to the second exemplary embodiment, a state in which, after applying the adhesive, a process of laminating a substrate is finished;

FIGS. 10A through 10C are drawings showing forms in which placement of the sheet-shaped member is different, in the substrate with a built-in semiconductor element relating to the second exemplary embodiment; and

FIG. 11 is a drawing showing a substrate with a built-in semiconductor element in which an underfill material is filled between a semiconductor element and a substrate.

### DETAILED DESCRIPTION

Exemplary embodiments of the present invention are described in detail hereinafter with reference to the drawings.

### First Exemplary Embodiment

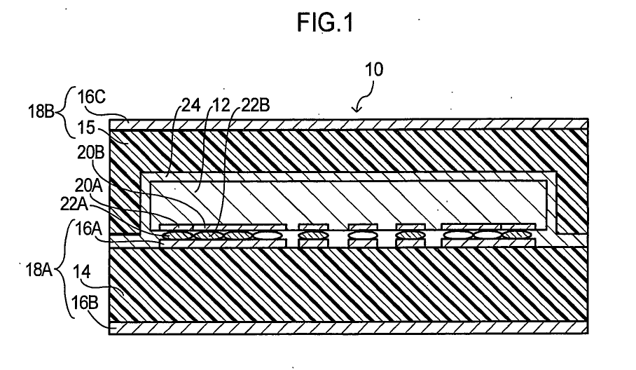

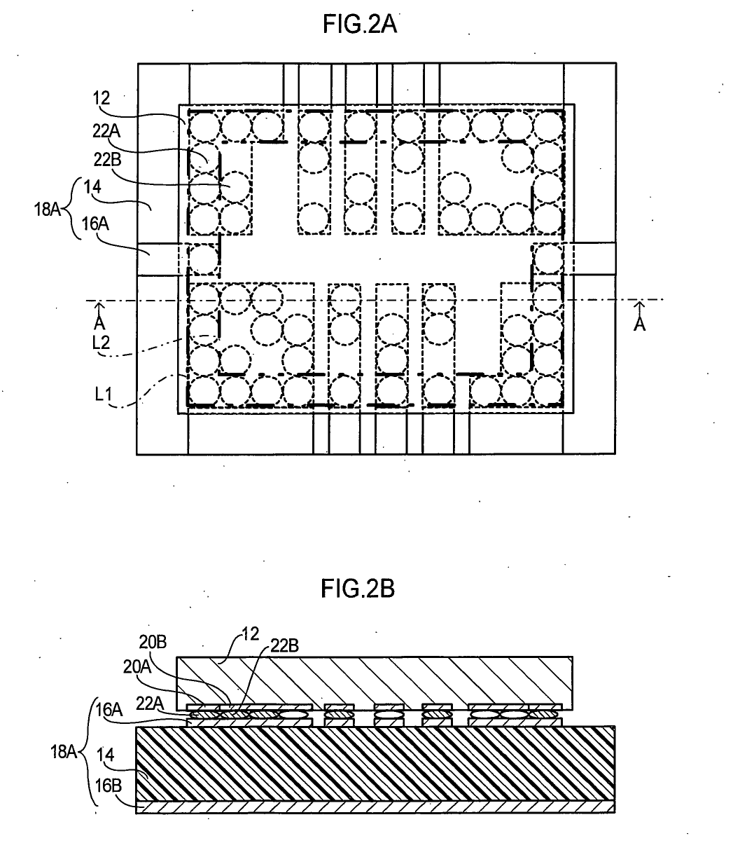

FIG. 1 is a longitudinal sectional view showing a substrate 10 with a built-in semiconductor element relating to the present first exemplary embodiment. A method of fabricating the substrate 10 with a built-in semiconductor element is explained by using FIGS. 2A through 4B.

Note that, in the substrate 10 with a built-in semiconductor element relating to the present first exemplary embodiment, in order to operate in a high-frequency band (millimeter wave band), a semiconductor element that is structured to include a distributed constant circuit and at which the circuit pattern is designed by using a CPW (Coplanar Waveguide), is used as a semiconductor element 12.

FIG. 2A is a plan view showing a finished state of a process of packaging (flip-chip packaging) the semiconductor element 12 on a substrate 18A, in which a first metal layer 16A and a second metal layer 16B are laminated on the both surfaces of a dielectric layer 14, such that the surface at which the distributed constant circuit is formed faces the first metal layer 16A of the substrate 18A. FIG. 2B is a sectional view along line A-A of FIG. 2A.

Note that, in the substrate 10 with a built-in semiconductor element relating to the present first exemplary embodiment, Teflon® is used as the dielectric layer 14 and a dielectric layer 15 that will be described later. However, the present invention is not limited to the same, and another dielectric material or a ceramic material or the like may be used.

In the substrate 10 with a built-in semiconductor element relating to the present first exemplary embodiment, a double-sided copper-clad laminated plate, in which the first metal layer 16A and the second metal layer 16B are made to be the copper plates, is used as the substrate 18A, but the present invention is not limited to the same. The first metal layer 16A and the second metal layer 16B may be made to be metal plates other than copper plates. Or, another substrate may be used provided that it is a substrate at which the first metal layer 16A is layered on the dielectric layer 14, such as a substrate in which the second metal layer 16B is not laminated on the dielectric layer 14 (a single-sided copper-clad laminated plate), or the like.

At the semiconductor element 12 relating to the present first exemplary embodiment, plural bonding pads 20A are formed at a peripheral region of the surface facing the substrate 18A (in FIG. 2A, the region that is at the inner side of a one-dot chain line L1 and the outer side of a two-dot chain line L2), and plural bonding pads 20B are formed at a region (hereinafter called “inner side region”) that is further toward the inner side than the two-dot chain line L2 of the peripheral region.

Before the process of flip-chip packaging is carried out, a process of forming the bonding pads 20A, 20B is carried out in advance on the semiconductor element 12.

On the other hand, the first metal layer 16A of the substrate 18A is layered as a wiring layer that includes a signal layer, a ground layer corresponding to the ground of the peripheral region of the semiconductor element 12 and the inner side region of the semiconductor element, and the like.

At the semiconductor element 12, the bonding pads 20A and the first metal layer 16A are connected by solder bumps 22A serving as electrically-conductive members, and the bonding pads 20B and the first metal layer 16A are connected by solder bumps 22B serving as supporting members (connecting members).

In this way, at the substrate 10 with a built-in semiconductor element relating to the present first exemplary embodiment, the bonding pads 20B of the semiconductor element 12 and the first metal layer 16A of the substrate 18A are electrically connected by the solder bumps 22B that are interposed between the semiconductor element 12 and the substrate 18A.

Note that, at the semiconductor element 12 in the present first exemplary embodiment, signal lines and bias circuits are formed at the inner side region, and the bonding pads 20B are formed at the region that is the ground other than the region at which the signal lines and the bias circuits are formed at the inner side region of the semiconductor element 12. Namely, the solder bumps 22B connect the ground of the semiconductor element 12 and the ground layer of the first metal layer 16A that is formed as the wiring layer.

Further, the solder bumps 22B in the present first exemplary embodiment are disposed at the inner side region, before the semiconductor element 12 and the first metal layer 16A are connected by the solder bumps 22A. Note that the solder bumps 22A, 22B may be disposed by being formed on the semiconductor element 12, or may be disposed by being formed on the substrate 18A.

The bonding pads 20B, that are connected to the first metal layer 16A by the solder bumps 22B, may be formed at uniform intervals at the inner side region. However, as shown in FIG. 2A, it is desirable to form the bonding pads 20B randomly at the inner side region. This is because, at the semiconductor element 12 that operates in a high-frequency band, by forming the bonding pads 20B at uniform intervals, standing waves are generated, and the standing waves may affect the operation of the semiconductor element 12.

In the substrate 10 with a built-in semiconductor element relating to the present first exemplary embodiment, the solder bumps 22B are used as supporting members. However, the present invention is not limited to the same, and other supporting members may be used provided that they are electrically-conductive, such as bumps formed of another metal such as gold, silver or the like, or the like.

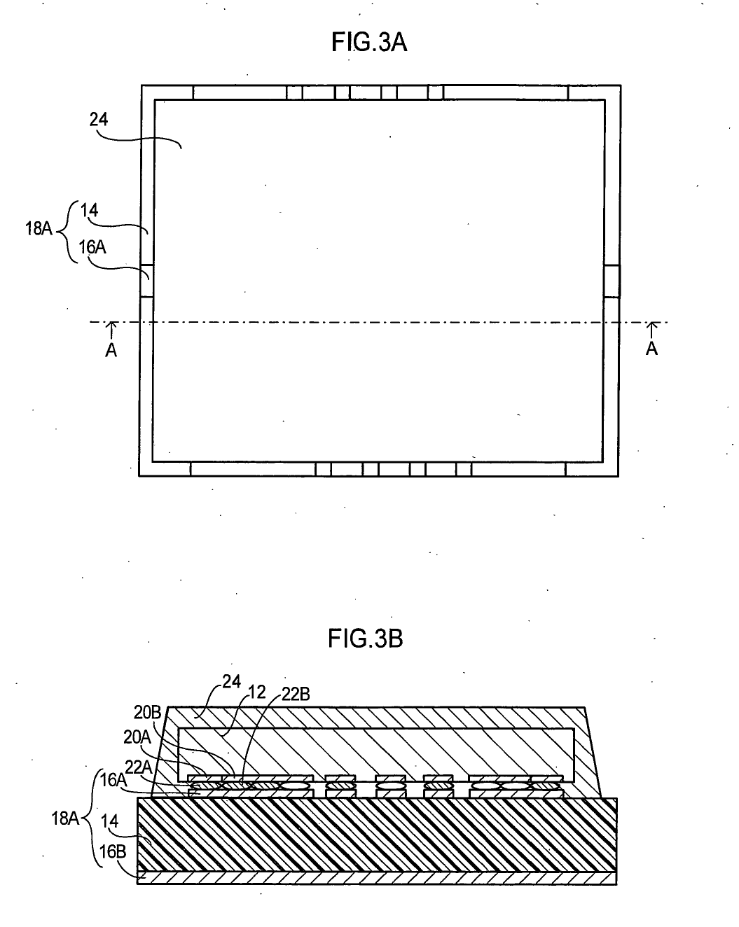

In the next process, after the semiconductor element 12 is flip-chip packaged on the substrate 18A, an adhesive 24 is applied on the substrate 18A and the semiconductor element 12, without an underfill material being filled between the substrate 18A and the semiconductor element 12. FIG. 3A is a plan view of a state in which the process of applying the adhesive 24 is finished, and FIG. 3B is a sectional view along line A-A of FIG. 3A.

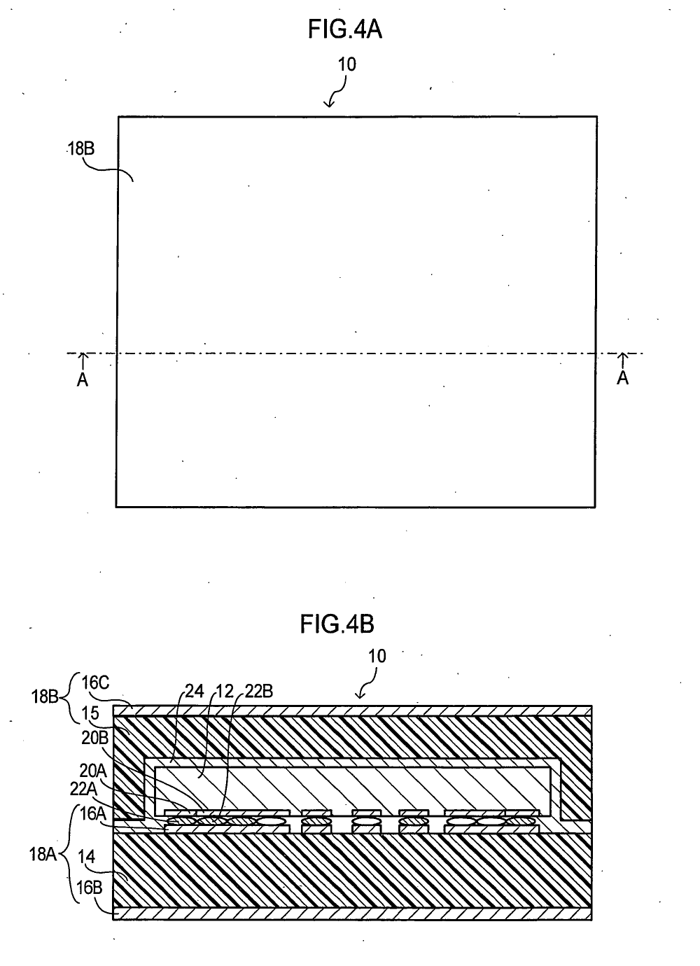

In the next process, a substrate 18B is laminated on the substrate 18A and the semiconductor element 12 that are in the state in which the adhesive 24 is applied thereto. FIG. 4A is a drawing showing a state in which the process of laminating the substrate 18B is finished and the substrate 10 with a built-in semiconductor element is completed. FIG. 4B is a sectional view along line A-A of FIG. 4A (the same drawing as FIG. 1).

At the substrate 18B, a third metal layer 16C is layered on the dielectric layer 15, and a hole, that corresponds to the thickness of the semiconductor element 12 and the solder bumps 22A, 22B, is provided in the side of the dielectric layer 15 facing the semiconductor element 12. The substrate 18B is laminated by the adhesive 24 such that the semiconductor element 12 is positioned in the hole.

Then, because the semiconductor element 12 and the substrate 18A are connected by the plural bonding pads 20A, 20B and the solder bumps 22A, 22B, the load that is applied to the semiconductor element 12 and that arises when the substrates 18A, 18B are laminated, i.e., when the substrate 10 with a built-in semiconductor element is fabricated, is dispersed by the solder bumps 22A, 22B, and the semiconductor element 12 is protected from this load.

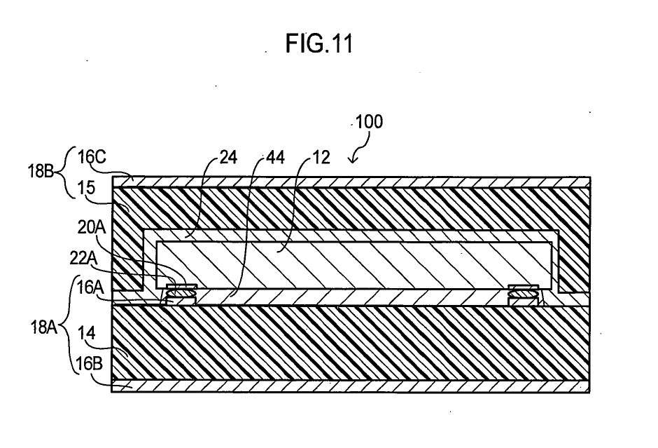

On the other hand, in a substrate 100 with a built-in semiconductor element in which the semiconductor element 12 is fixed by an underfill material 44 as shown in FIG. 11 for example, the region between the substrate 18A and the inner side region of the semiconductor element 12 where the signal lines and the bias circuits are formed is filled with the underfill material 44. Therefore, there is the possibility that the semiconductor element 12 will be affected by the dielectric that structures the underfill material 44. In contrast, in the substrate 10 with a built-in semiconductor element relating to the present first exemplary embodiment, due to the solder bumps 22B being interposed between the semiconductor element 12 and the substrate 18A, an air layer of about several tens of μm arises between the semiconductor element 12 and the dielectric layer 14 at the region where the signal lines and the bias circuits are formed of the inner side region of the semiconductor element 12, and effects of the dielectric layer 14 on the operation of the semiconductor element 12 can be suppressed.

Further, the semiconductor element 12 is connected to the first metal layer 16A (wiring layer) of the substrate 18A that includes a very large ground pattern, via the bonding pads 20A and the solder bumps 22A, and the bonding pads 20B and the solder bumps 22B. Therefore, the heat that is generated at the semiconductor element 12 can be transferred to the first metal layer 16A. Due thereto, as compared with a case in which an underfill material is filled between the semiconductor element 12 and the substrate 18A, the heat-dissipating efficiency of the semiconductor element 12 improves, and the reliability of operation of the semiconductor element 12 can be improved.

As described above in detail, the substrate 10 with a built-in semiconductor element relating to the present first exemplary embodiment has: the substrate 18A at which the first metal layer 16A is layered on the dielectric layer 14; the semiconductor element 12 that is structured to include a distributed constant circuit, and at which the plural bonding pads 20A are formed at the peripheral region of the surface facing the substrate 18A, the semiconductor element 12 being electrically connected to the first metal layer 16A by the solder bumps 22A that have electrical conductivity and correspond to the plural bonding pads 20A; the solder bumps 22B that are disposed at the inner side region that is further toward the inner side than the peripheral region of the semiconductor element 12, and that are interposed between the semiconductor element 12 and the substrate 18A and support the semiconductor element 12; and the substrate 18B that is laminated on the substrate 18A and the semiconductor element 12.

Due thereto, effects of a dielectric on the semiconductor element 12, that is structured to include a distributed constant circuit, are suppressed, and the semiconductor element 12 can be protected from load that is applied thereto at the time of fabricating the substrate 10 with a built-in semiconductor element.

Further, in accordance with the substrate 10 with a built-in semiconductor element relating to the present first exemplary embodiment, at the semiconductor element 12, the signal lines are formed at the inner side region, and the solder bumps 22B are disposed at regions other than the regions at which the signal lines are formed. Due thereto, an air layer is formed between the signal lines of the semiconductor element 12 and the dielectric layer 14 that structures the substrate 18A, and therefore, effects of the dielectric layer 14 on the operation of the semiconductor element 12 can be suppressed more effectively.

In the substrate 10 with a built-in semiconductor element relating to the present first exemplary embodiment, at the substrate 18A, the first metal layer 16A that is the wiring layer is layered on the region that faces the peripheral region of the semiconductor element 12 and at the region that faces the inner side region. At the semiconductor element 12, the plural bonding pads 20B are formed at the inner side region, and the plural solder bumps 22B are formed so as to correspond to the plural bonding pads formed at the inner side region, and electrically connect the first metal layer 16A, that is layered on the region of the substrate 18A facing the inner side region, and the plural bonding pads 20B that are formed at the inner side region.

Due thereto, the load, that is applied to the semiconductor element 12 and that arises when the substrate 18B is laminated, is dispersed by the solder bumps 22B and the bonding pads 20B that are formed at the inner side region, and the semiconductor element 12 is protected from this load. Further, because the air layer is formed between the semiconductor element 12 and the dielectric layer 14, effects of the dielectric layer 14 on the operation of the semiconductor element 12 can be suppressed more effectively.

Further, in accordance with the substrate 10 with a built-in semiconductor element relating to the present first exemplary embodiment, at the semiconductor element 12, the plural bonding pads 20B, that are connected to the first metal layer 16A by the solder bumps 22B, are formed randomly at the inner side region. Therefore, standing waves can be prevented from being generated at the substrate 10 with a built-in semiconductor element.

### Second Exemplary Embodiment

In the present second exemplary embodiment, the supporting member is disposed at the inner side region of the semiconductor element 12 and is interposed between the semiconductor element 12 and the substrate 18A and supports the semiconductor element 12, is made to be a sheet-shaped member that includes a dielectric.

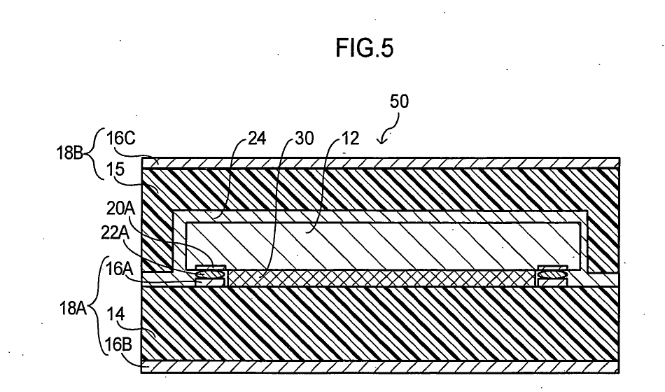

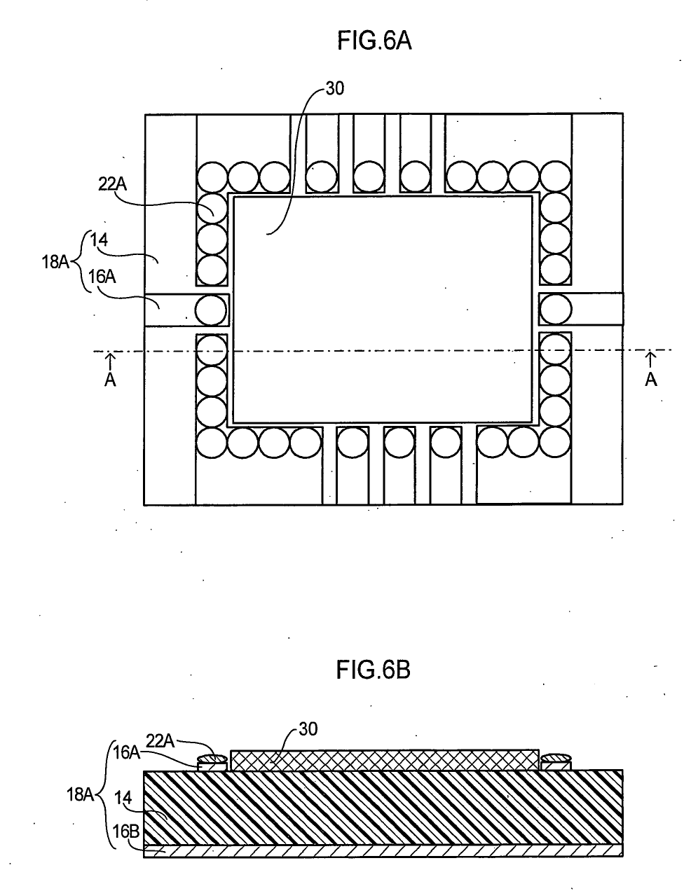

FIG. 5 is a longitudinal sectional view showing a substrate 50 with a built-in semiconductor element relating to the present second exemplary embodiment. A method of fabricating the substrate 50 with a built-in semiconductor element is described by using FIGS. 6 through 9. Note that structures that are similar to those of the substrate 10 with a built-in semiconductor element relating to the first exemplary embodiment are denoted by the same reference numerals, and description thereof is omitted.

FIG. 6A is a plan view of a state in which a process of disposing a sheet-shaped member 30 at the substrate 18A is finished. FIG. 6B is a sectional view along line A-A of FIG. 6A.

In the substrate 50 with a built-in semiconductor element relating to the present second exemplary embodiment, the sheet-shaped member 30, that has a thickness of the same extent as the sum of the thickness of the solder bump 22A and the thickness of the first metal layer 16A, is disposed at the inner side region of the semiconductor element 12. A member formed of a material, whose dielectric constant and dielectric dissipation factor values are smaller than those of an underfill material having characteristics of the same extent as FR4 (Flame Retardant Type 4) (i.e., a dielectric constant of about 4 and a dielectric dissipation factor of about 0.02), e.g., a member formed of a graft copolymer or a borazine based compound or the like whose dielectric constant is 2 and whose dielectric dissipation factor is 0.0015, is used as the sheet-shaped member 30. Further, when the sheet-shaped member 30 is disposed at the substrate 18A, the shaped-shaped member 30 may be adhered to the substrate 18A by an adhesive.

Note that, in the substrate 50 with a built-in semiconductor element relating to the present second exemplary embodiment, the solder bumps 22A are formed in advance on the first metal layer 16A as shown in FIGS. 6A and 6B. However, the present invention, is not limited to the same. The solder bumps 22A may be formed in advance on the bonding pads 20A of the semiconductor element 12, without forming the solder bumps 22A on the first metal layer 16A.

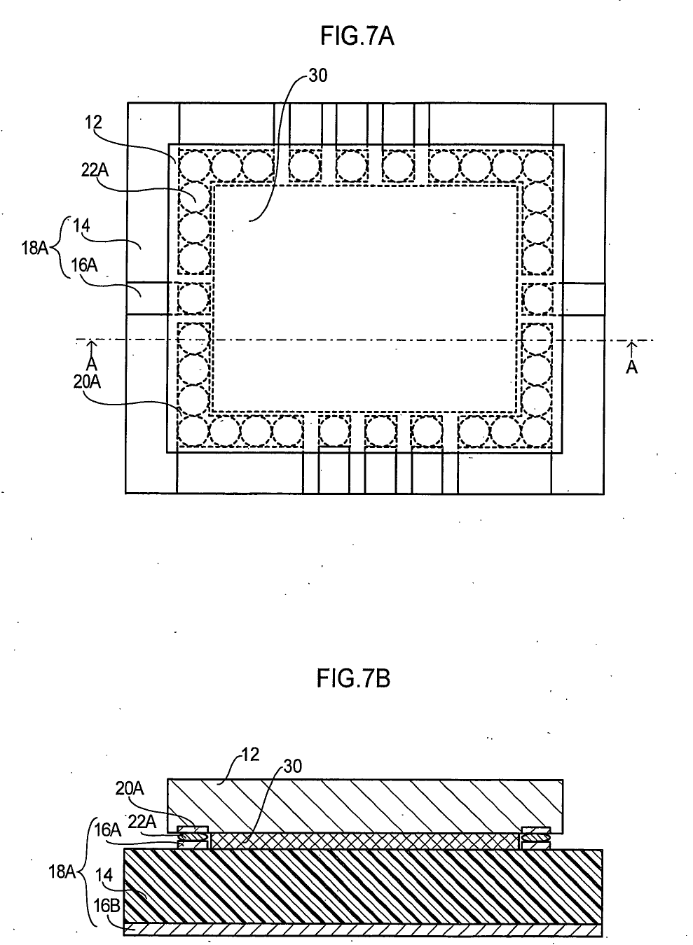

In the next process, the semiconductor element 12 is packaged on the substrate 18A in the state in which the sheet-shaped member 30 is interposed between the semiconductor element 12 and the substrate 18A. FIG. 7A is a plan view of the substrate 18A on which the semiconductor element 12 is packaged, and FIG. 7B is a sectional view along line A-A of FIG. 7A.

Note that, when the semiconductor element 12 is packaged on the substrate 18A, the sheet-shaped member 30 and the semiconductor element 12 may be adhered by an adhesive.

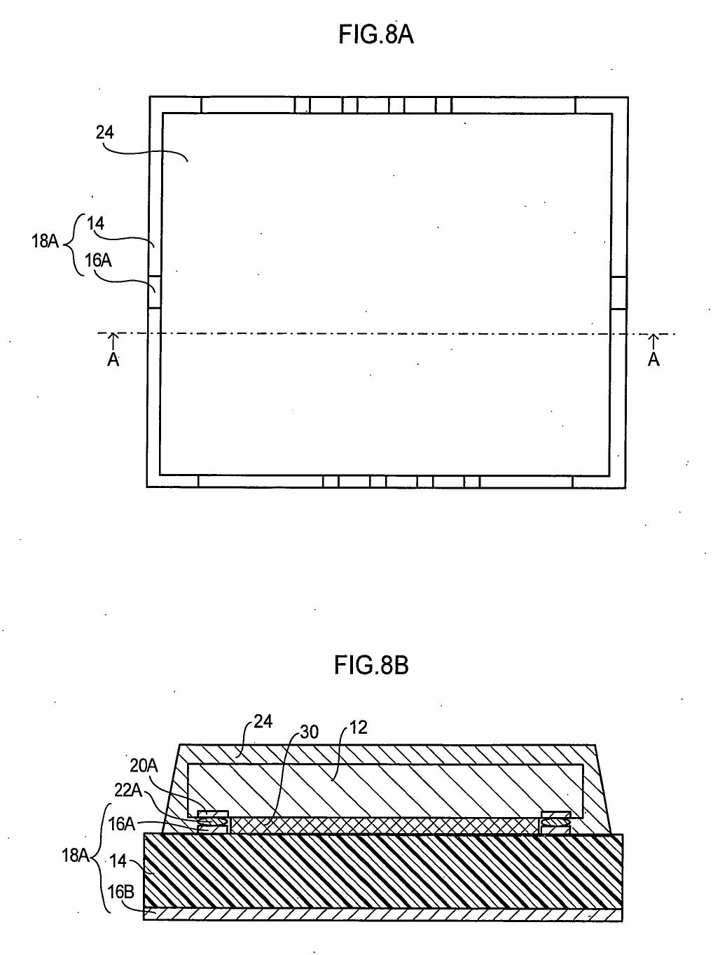

In the next process, the adhesive 24 is applied on the substrate 18A on which the semiconductor element 12 is packaged. FIG. 8A is a plan view of the substrate 18A on which the adhesive 24 is applied, and FIG. 8B is a sectional view along line A-A of FIG. 8A.

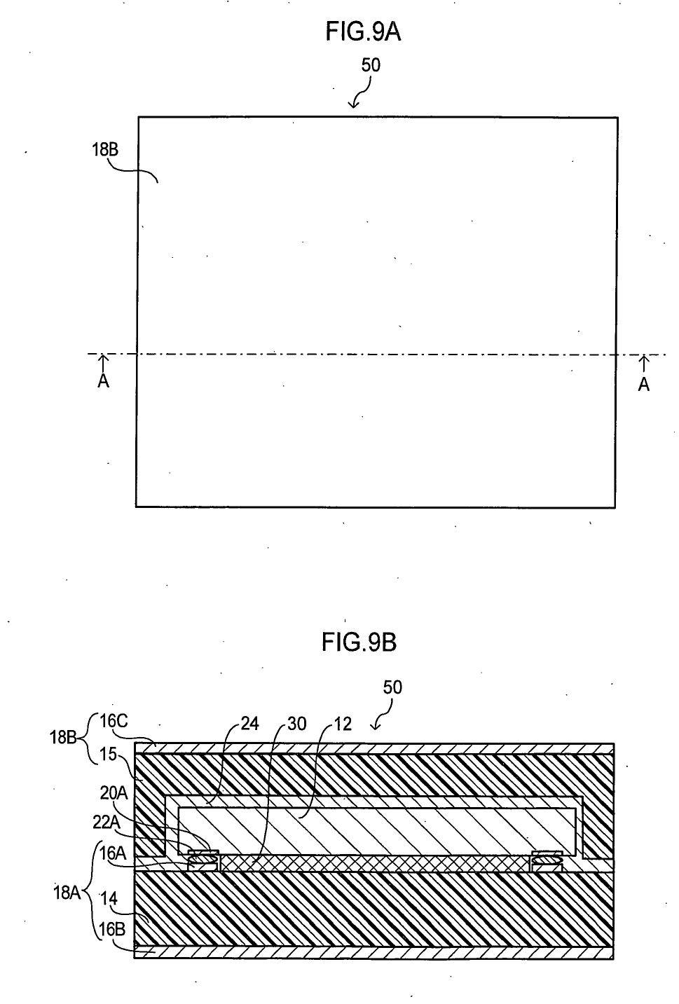

In the next process, the substrate 18B is laminated on the substrate 18A that is in the state in which the adhesive 24 is applied thereto. FIG. 9A is a plan view showing a state in which the process of laminating the substrate 18B is finished, and the substrate 50 with a built-in semiconductor element is completed. FIG. 9B is a sectional view along line A-A of FIG. 9A (the same drawing as FIG. 5).

In the substrate 50 with a built-in semiconductor element that is fabricated by the above-described processes, the sheet-shaped member 30 is interposed between the semiconductor element 12 and the substrate 18A. Therefore, the load that is applied to the semiconductor element 12 that arises when the substrates 18A, 18B are laminated, i.e., when the substrate 50 with a built-in semiconductor element is fabricated, is dispersed by the sheet-shaped member 30, and the semiconductor element 12 is protected from this load. Further, as compared with the underfill material 44 that is used in the substrate 100 with a built-in semiconductor element shown in FIG. 11, the effects of the dielectric layer on the operation of the semiconductor element 12 can be suppressed because a dielectric whose dielectric constant and dielectric dissipation factor values are small is used as the sheet-shaped member 30.

As described above in detail, in accordance with the substrate with a built-in semiconductor element relating to the present second exemplary embodiment, because the supporting member is made to be the sheet-shaped member 30 that includes a dielectric, the load that is applied to the semiconductor element 12 and that arises when the substrate 18B is laminated is dispersed by the sheet-shaped member 30. The semiconductor element 12 is protected from this load, and the range of selection of dielectrics for supporting the semiconductor element 12 can be broadened.

Note that, in the substrate with a built-in semiconductor element relating to the present second exemplary embodiment, the sheet-shaped member 30 may be formed of plural, different materials.

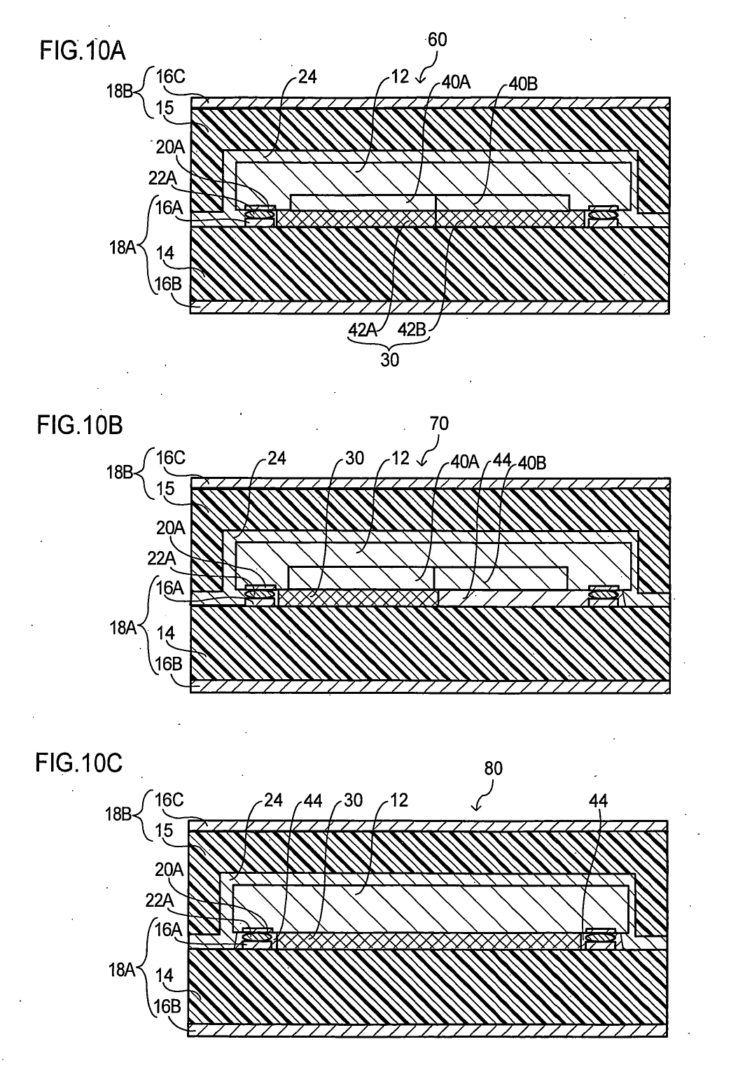

When the semiconductor element 12 is structured by circuits 40A, 40B whose operating frequencies are different as in the case of a substrate 60 with a built-in semiconductor element shown in FIG. 10A, plural dielectrics 42A, 42B, at which at least one of the dielectric constant and the dielectric dissipation factor differs, are formed as the sheet-shaped member 30 in accordance with the operating frequencies of the circuits 40A, 40B.

For example, if the circuit 40A is a distributed constant circuit and the circuit 40B is a lumped constant circuit, for example, a member formed of a graft copolymer or a borazine based compound or the like whose dielectric constant is 2 and whose dielectric dissipation factor is 0.0015 is used as the dielectric 42A that forms the sheet-shaped member 30, and a dielectric having characteristics of the same extent as an underfill material is used as the dielectric 42B.

Note that, when the substrate 50 with a built-in semiconductor element has the plural semiconductor elements 12 that have circuits whose operating frequencies are different, plural dielectrics, at which at least one of the dielectric constant and the dielectric dissipation factor differs, may be formed as the sheet-shaped member 30 in accordance with the operating frequencies of the circuits of the respective semiconductor elements 12.

Due thereto, even if the semiconductor element 12 is structured by combining the plural circuits 40A, 40B whose operating frequencies are different, dielectrics that are respectively suited to the respective circuits can be disposed between the semiconductor element 12 and the substrate 18A.

Further, if the semiconductor element 12 is structured by plural circuits whose operating frequencies are different, the sheet-shaped member 30 may be disposed so as to correspond to the position of the circuit whose operating frequency is relatively high, and an underfill material may be filled so as to correspond to the position of the circuit whose operating frequency is relatively low.

For example, if the circuit 40A is structured by a distributed constant circuit and the circuit 40B is structured by a lumped constant circuit as is the case of a substrate 70 with a built-in semiconductor element shown in FIG. 10B, the sheet-shaped member 30 is disposed so as to correspond to the position of the circuit 40A, and the underfill material 44 is filled so as to correspond to the position of the circuit 40B.

Further, if the substrate 50 with a built-in semiconductor element has the plural semiconductor elements 12 having circuits whose operating frequencies are different, the sheet-shaped member 30 may be disposed so as to correspond to the position of the circuit whose operating frequency is relatively high, and the underfill material 44 may be filled so as to correspond to the position of the circuit whose operating frequency is relatively low.

In this way, effects of a dielectric on the semiconductor element 12 that is structured to include a distributed Constant circuit are suppressed, and the fixing of the semiconductor element 12 to the substrate can be made to be secure.

Further, as is the case of a substrate 80 with a built-in semiconductor element shown in FIG. 10C, the sheet-shaped member 30 may be disposed at the inner side region of the semiconductor element 12, and the underfill material 44 may be filled at the periphery of the sheet-shaped member 30.

The sheet-shaped member 30 may be made to be a structure in which the regions corresponding to the signal lines of the semiconductor element 12 are hollowed-out, and an air layer is formed between these signal lines and the dielectric layer 14. Or, the sheet-shaped member 30 may be made to be a structure that contains air therein, by making the sheet-shaped member 30 be a mesh structure.

Although the present invention has been described above by using the respective exemplary embodiments, the technical scope of the present invention is not limited to the scope described in the exemplary embodiments. Various changes and improvements may be added to the respective embodiments within a scope that does not deviate from the gist of the present invention, and forms to which such changes or improvements have been added are also included within the technical scope of the present invention.

Further, the above respective exemplary embodiments do not limit the present invention, nor is it the case that all of the combinations of features described in the exemplary embodiments are essential to the means of the present invention for solving the problems of the conventional art. Inventions of various stages are included in the above exemplary embodiments, and various inventions can be extracted by combining plural structural conditions that are disclosed. Even if some of the structural conditions among all of the structural conditions that are shown in the above exemplary embodiments are omitted or substituted, such structures from which some structural conditions are omitted can be extracted as inventions provided that the effects of the present invention are obtained.

For example, in the above-described respective exemplary embodiments, a semiconductor element at which the circuit pattern is designed by using a CPW is used as the semiconductor element, but the present invention is not limited to the same. A semiconductor element using microstrip lines may be used as the semiconductor element.

In the case of this form, in the first exemplary embodiment, ground is formed at the regions except for the microstrip lines at the inner side region of the semiconductor element, and the bonding pads are formed so as to correspond to the formed ground. Then, the ground lines are formed so as to correspond to the bonding pads, at the region of the substrate facing the inner side region of the semiconductor element. The bonding pads formed at the semiconductor element and the ground lines formed at the substrate are electrically connected by bumps.

Further, the present invention is not limited to a semiconductor element that is structured by using a CPW or microstrip lines, and may be a form using an element at which there is the possibility that the operation thereof will be affected by a dielectric, such as a semiconductor laser element, a switching element, a resistor, an inductor, a capacitor, or the like.

Still further, the structures of the substrates with a built-in semiconductor element that were described in the above respective exemplary embodiments (see FIG. 1 through FIG. 10C) are examples, and, of course, unnecessary portions may be deleted therefrom and new portions may be added thereto within a scope that does not deviate from the gist of the present invention.

What is claimed is:

1. A substrate with a built-in semiconductor element, comprising:
a first substrate at which a wiring layer is layered on a dielectric layer;
a semiconductor element that is structured to include a distributed constant circuit, and at which a plurality of bonding pads are formed at a peripheral region of a surface that faces the first substrate, and that is electrically connected to the wiring layer by an electrically-conductive member that has electrical conductivity and corresponds to the plurality of bonding pads;
a supporting member that is disposed at an inner side region that is further toward an inner side than the peripheral region of the semiconductor element, and that is interposed between the semiconductor element and the first substrate and supports the semiconductor element; and
a second substrate that is laminated to the first substrate and the semiconductor element.

2. The substrate with a built-in semiconductor element of claim 1, wherein
signal lines are formed at the inner side region of the semiconductor element, and
the supporting member is disposed at a region other than regions where the signal lines are formed.

3. The substrate with a built-in semiconductor element of claim 2, wherein
at the first substrate, the wiring layer is layered at a region that faces the peripheral region of the semiconductor element and at a region that faces the inner side region,
at the semiconductor element, a plurality of bonding pads are formed at the inner side region, and
the supporting member is a plurality of connecting members that are electrically-conductive and are formed so as to correspond to the plurality of bonding pads formed at the inner side region, and that electrically connect the wiring layer, that is layered at the region of the first substrate that faces the inner side region, and the plurality of bonding pads that are formed at the inner side region.

4. The substrate with a built-in semiconductor element of claim 3, wherein, at the semiconductor element, the plurality of bonding pads, that are connected to the wiring layer by the connecting members, are formed randomly at the inner side region.

5. The substrate with a built-in semiconductor element of claim 1, wherein the supporting member is a sheet-shaped member that includes a dielectric.

6. The substrate with a built-in semiconductor element of claim 5, wherein
the semiconductor element comprises a plurality of circuits having different operating frequencies, or comprises a plurality of semiconductor elements having circuits having different operating frequencies, and
the sheet-shaped member is structured so as to include a plurality of dielectrics at which at least one of a dielectric constant and a dielectric dissipation factor differ in accordance with the operating frequencies of the circuits of the semiconductor element.

7. The substrate with a built-in semiconductor element of claim 5, wherein
the semiconductor element comprises a plurality of circuits having different operating frequencies, or comprises a plurality of semiconductor elements having circuits having different operating frequencies,
the sheet-shaped member is disposed so as to correspond to a position of the circuit that has a relatively high operating frequency, and
an underfill material is filled so as to correspond to a position of the circuit having a relatively low operating frequency.
